(19) United States
(12) Patent Application Publication
(10) Pub. No.: US 2017/0250343 A1
(43) Pub. Date: Aug. 31, 2017

(54) SHADOW MASK AND METHOD OF MANUFACTURING A DISPLAY DEVICE

(71) Applicant: Japan Display Inc., Minato-ku (JP)

(72) Inventor: Takeshi OKAWARA, Minato-ku (JP)

(73) Assignee: Japan Display Inc., Minato-ku (JP)

(21) Appl. No.: 15/392,735

(22) Filed: Dec. 28, 2016

(30) Foreign Application Priority Data
Feb. 25, 2016 (JP) 2016-034017

(51) Int. Cl. H01L 51/00; H01L 51/56; C23C 14/04

(52) U.S. Cl. CPC H01L 51/0011; C23C 14/042; H01L 51/56

(57) ABSTRACT

A shadow mask includes a first surface arranged in such a way as to face a film deposition target, and a second surface arranged in such a way as to be exposed to a film deposition material. Each of the first surface and the second surface has an uneven surface, and the second surface is more uneven than the first surface.

### CROSS-REFERENCE TO RELATED APPLICATION

The present application claims priority from the Japanese Application JP 2016-34017 filed on Feb. 25, 2016, the content of which is hereby incorporated by reference into this application.

### BACKGROUND OF THE INVENTION

1. Field of the Invention

The present invention relates to a shadow mask and a method of manufacturing a display device using a shadow mask.

2. Description of the Related Art

Recently, an organic EL display device using an organic EL (electro-luminescent) element has been in practical use. In some cases, a vapor deposition method is employed at the time of forming an organic layer and a cathode electrode of the organic EL element.

In order to form the above organic layer and cathode electrode in a desired shape, a shadow mask formed with multiple fine slits arranged in parallel is used. As display devices have higher definition and higher image quality, the development of the shadow mask is under way. The shadow mask is also called a vapor deposition mask or metal mask.

JP2007-95411A discloses that, in a metal mask for organic EL for forming an organic EL layer on a substrate, a resin convex part is provided on the metal mask for organic EL, thus preventing the metal mask and the substrate from contacting each other and preventing damage to the substrate surface due to foreign matters and scratches.

JP2003-253434A discloses that surface roughening is carried out on the substrate contact surface side of a metal mask, thus reducing the contact area with the substrate and restraining damage to the substrate, and that surface roughening is carried out also on the vapor deposition source side, thus preventing the separation of the vapor deposition material.

### SUMMARY OF THE INVENTION

If the vapor deposition source side of the metal mask is flat, as in JP2007-95411A, the film deposited on the metal mask surface may come off. If the film deposited on the metal mask surface comes off, the film that comes off contaminates the vapor deposition source, and impurities get into the film formed by the contaminated vapor deposition source.

Meanwhile, in the configuration in which a convex part and a concave part are provided on both sides of the metal mask, as in JP2003-253434A, if the thickness of the metal mask is thin and the convex part and the concave part formed on both sides are large, the strength of the metal mask is reduced and the metal mask may twist.

In view of the foregoing problems, it is an object of the invention to secure sufficient strength of a shadow mask which restrains damage to the substrate and in which the film deposition material deposited on the surface will not come off easily, and to provide a display device manufactured using this shadow mask. According to one aspect of the present invention, a shadow mask includes a first surface arranged in such a way as to face a film deposition target, and a second surface arranged in such a way as to be exposed to a film deposition material. Each of the first surface and the second surface has an uneven surface, and the second surface is more uneven than the first surface.

In one embodiment of the present invention, the first surface has a planar irregular shape, and the second surface has a planar regular shape.

In one embodiment of the present invention, an average value of one or more heights and one or more depths from a reference surface, of one or more tops and one or more bottoms in the uneven surface is greater on the second surface than on the first surface.

In one embodiment of the present invention, an average value of a space between one or more tops and one or more bottoms in the uneven surface as viewed in a plan view is greater on the second surface than on the first surface.

In one embodiment of the present invention, the planar regular shape on the second surface is in such a shape that the bottoms are surrounded by tops continuously. In one embodiment of the present invention, the tops and the bottoms are formed in the shape of a lattice as viewed in a plan view.

In one embodiment of the present invention, the tops and the bottoms are formed in the shape of stripes as viewed in a plan view.

In one embodiment of the present invention, the tops and the bottoms are formed in the shape of circles as viewed in a plan view. In one embodiment of the present invention, a frame is provided in such a way as to hold a peripheral edge part of the shadow mask. The frame has a first frame surface arranged on the side of the film deposition target, and a second frame surface arranged in such a way as to be exposed to the film deposition material. Each of the first frame surface and the second frame surface has an uneven surface, and the second frame surface is more uneven than the first frame surface.

According to another aspect of the present invention, there is provided a method of manufacturing a display device including a light emitting element layer. The method includes a step of preparing a shadow mask having a first surface and a second surface, wherein each of the first surface and the second surface has an uneven surface and wherein the second surface is more uneven than the first surface, and a step of arranging the shadow mask in such a way that the first surface faces a substrate while the second surface is exposed to a film deposition material, and forming the light emitting element layer while patterning the layer by vapor deposition.

### BRIEF DESCRIPTION OF THE DRAWINGS

FIG. 1 schematically shows a shadow mask according to an embodiment of the invention.

FIG. 2 is an enlarged view of a part of the shadow mask.

FIG. 3 is a cross-sectional view showing a cross section of FIG. 2.

FIGS. 4A to 4C illustrate an example in which the shapes of tops and bottoms formed on the shadow mask.

FIG. 5 illustrates a method of manufacturing a display device.

FIG. 6 illustrates the process of depositing a film using the shadow mask.

### DETAILED DESCRIPTION OF THE INVENTION

Hereinafter, each embodiment of the invention will be described with reference to the drawings. The disclosure is only an example. As a matter of course, changes and modifications which a person skilled in the art can readily think of without departing from the spirit of the invention are included in the scope of the invention. In order to clarify the explanation, the drawings may schematically show the width, thickness, shape and the like of each part, compared with the actual configuration. However, this is simply an example and should not limit the interpretation of the invention. In the description and the drawings, elements similar to those described with reference to drawings that are already mentioned may be denoted by the same reference signs and detailed description of such elements maybe omitted when it is appropriate.

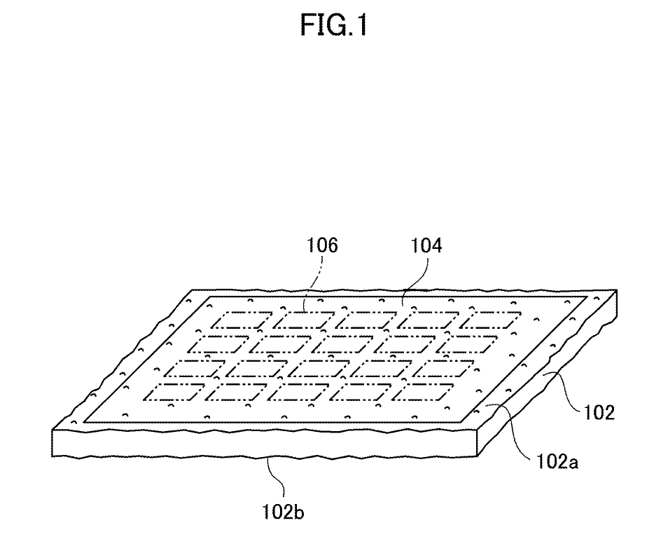

FIG. 1 schematically shows a shadow mask according to an embodiment of the invention. FIG. 1 shows the shadow mask, as viewed from the side facing a film deposition target.

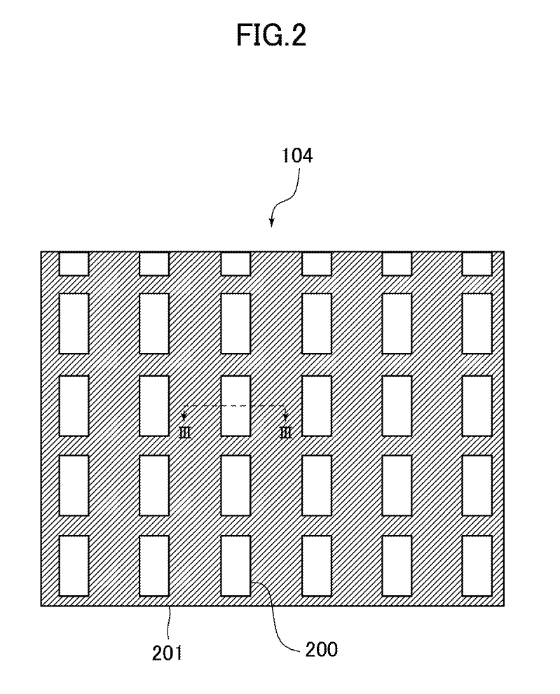

A shadow mask 104 is a thin plate-like member having an opening 200 (see FIG. 2) corresponding to a film deposition pattern. Specifically, for example, in the case where the film deposition target is a plurality of display panels formed on a single glass substrate, the shadow mask 104 has the opening 200 corresponding to the film deposition pattern at each of positions 106 corresponding to the plurality of display panels. The shadow mask 104 is formed, for example, of an invar material (36Ni—Fe) or Ni-plated film. Also, the shadow mask 104 is fixed to a frame 102 by welding.

The frame 102 is a frame-shaped member provided to hold the peripheral edges of the shadow mask 104, and has a first frame surface arranged on the side of the film deposition target and a second frame surface arranged in such a way as to be exposed to the film deposition material. Specifically, the frame 102 has a first frame surface arranged on the top side in the drawing of FIG. 1, and a second frame surface arranged on the bottom side. The shadow mask 104 is welded and thus fixed to the top side of the frame 102.

The shadow mask 104 is used for patterning in a film deposition process in which a film deposition material is deposited.

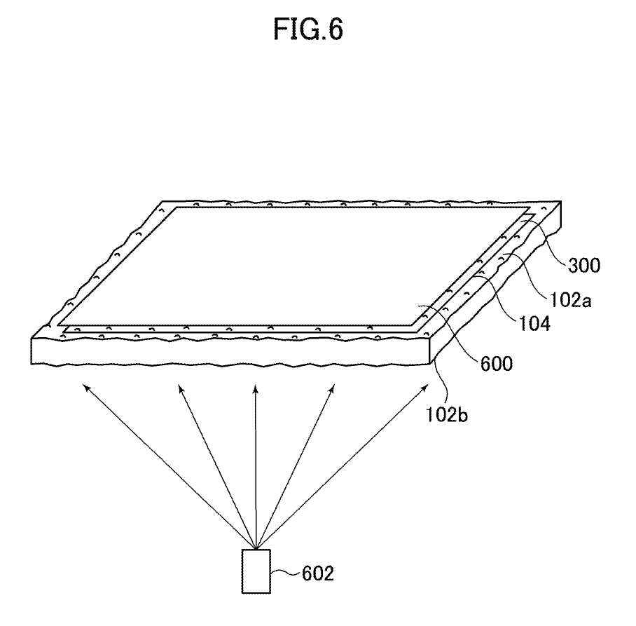

Specifically, for example, at the time of depositing the film deposition material, the shadow mask 104 is used in the state where a vapor deposition source 602 (see FIG. 6) or the like is arranged on the side with the frame 102 welded and where the film deposition target is arranged on the opposite side, as will be described in detail later.

The welded shadow mask 104 can be stripped off the frame 102. Therefore, in the case of changing the shape of the film deposition pattern, only the shadow mask 104 needs to be replaced, whereas the frame 102 can be used as it is. Therefore, the cost can be reduced.

Next, details of the shadow mask 104 will be described. FIG. 2 is an enlarged view of a part 201 of the area corresponding to a single display panel, of the positions 106 corresponding respectively to the plurality of display panels, in the shadow mask 104 shown in FIG. 1. As shown in FIG. 2, the shadow mask 104 has an opening 200 corresponding to the shape of a film be prepared. Specifically, the shadow mask 104 has a rectangular opening 200 corresponding to the shape of a film to be prepared for the display panel. The shape of the opening 200 defines the shape of the film to be formed on the film deposition target. While the shape of a film provided with the rectangular opening 200 corresponding to an organic light emitting element provided in one subpixel in the display panel is shown as an example in FIG. 2, the shape of the film is not limited to this example.

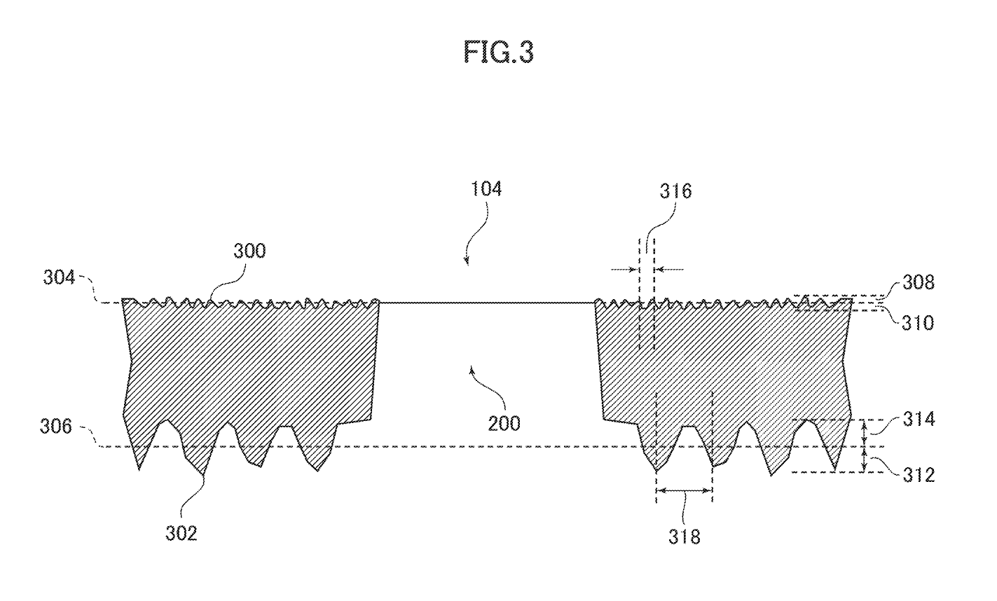

FIG. 3 shows a cross section of FIG. 2. As shown in FIG. 3, the shadow mask 104 has a first surface 300 arranged in such a way as to face the film deposition target, and a second surface 302 arranged in such a way as to be exposed to the film deposition material. Each of the first surface 300 and the second surface 302 has an uneven surface, and the second surface 302 is more uneven than the first surface 300.

For example, the first surface 300 and the second surface 302 are roughened in such a way that an average value of one or more heights and one or more depths from a reference surface, of one or more tops and one or more bottoms in the uneven surface, is greater on the second surface 302 than on the first surface 300.

Specifically, the first surface 300 and the second surface 302 are roughened in such away that the average value of one or more heights 312 and one or more depths 314 from a reference surface 306 of the second surface, of the tops and bottoms on the second surface 302, is greater than the average value of one or more heights 308 and one or more depths 310 from a reference surface 304 of the first surface, of the tops and bottoms on the first surface 300.

More specifically, it is desirable that the total value of the height 308 and the depth 310 from the reference surface 304 of the first surface, of the tops and bottoms formed on the first surface 300, is approximately 3 micrometers. That is, since it is common that impurities attached to the film deposition target are approximately 3 micrometers, the occurrence of scratches on the film deposition target can be prevented by forming tops and bottoms that are approximately 3 micrometers on the first surface 300.

Also, it is desirable that the total value of the height 312 and the depth 314 from the reference surface 306 of the second surface, of the tops and bottoms formed on the second surface 302, is approximately half the thickness of the shadow mask 104. That is, the twisting of the shadow mask 104 can be prevented by making the height of the tops and the depth of the bottoms approximately half the thickness of the shadow mask 104. Specifically, for example, it is desirable that the total value of the height 312 and the depth 314 from the reference surface 306 of the second surface, of the tops and bottoms formed on the second surface 302, is approximately 10 to 100 micrometers. Here, since both sides of the shadow mask 104 are roughened, the thickness varies depending on the position, to be more precise. Therefore, the thickness of the shadow mask 104 is defined as the length between the reference surface 304 of the first surface and the reference surface 306 of the second surface. By forming the second surface 302 has an uneven surface, the risk that the film deposition material deposited on the shadow mask 104 may come off can be reduced. That is, the film deposition material deposited in the concave parts formed on the second surface 302 come off less easily than the film deposition material deposited on a flat surface. Therefore, the deposited vapor deposition material can be prevented from coming off and contaminating the vapor deposition source 602 and the inside of the sputtering device or the like arranged on the side of the second surface 302. Moreover, by reducing the frequency of replacement of the shadow mask 104, the cost of cleaning the shadow mask 104 can be reduced.

The first surface 300 and the second surface 302 are roughened in such a way that an average value of a space between one or more tops and one or more bottoms as viewed in a plan view is greater on the second surface 302 than on the first surface 300. Specifically, the first surface 300 and the second surface 302 are roughened in such a way that a space 318 between a top provided on the second surface 302 and a top next to the former top is greater than a space 316 between a top provided on the first surface 300 and a top next to the former top.

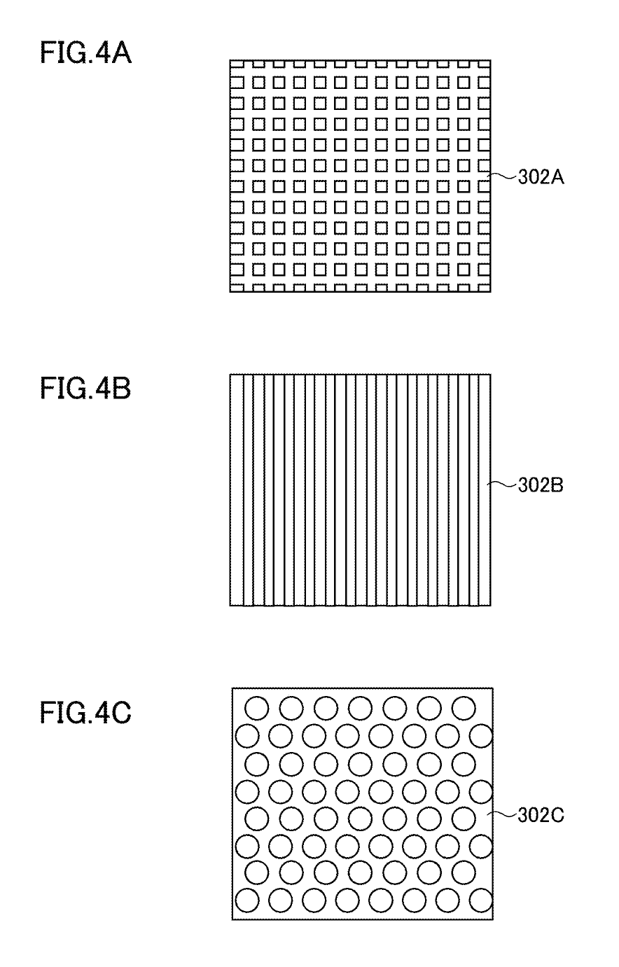

Moreover, in FIG. 3, the planar shapes are formed irregular both on the first surface 300 and on the second surface 302. However, the second surface 302 may has a planar regular shape, while the first surface 300 has a planar irregular shape. For example, the planar regular shape on the second surface 302 may be formed in such a shape that the bottoms are surrounded by the tops continuously. Specifically, the shape of the tops and the bottoms on a second surface 302A may be a lattice as viewed in a plan view, as shown in FIG. 4A. In FIG. 4A, the tops and the bottoms on the second surface 302A are formed in such a way that vertical stripe-like tops and horizontal stripe-like tops are superimposed. The shape of the tops and the bottoms on a second surface 302B may be stripes as viewed in a plane view, as shown in FIG. 4B. Moreover, the shape of the tops and the bottoms on a second surface 302C may be circles as viewed in a plan view, as shown in FIG. 4C, and may be columnar in a stereoscopic view. In this configuration, columnar top face may be formed, or columnar bottom face may be formed.

By varying the size and density of the tops and bottoms in the in-plane direction of the shadow mask 104, on the first surface 300 and the second surface 302, or by achieving a regular shape of the tops and bottoms formed on the second surface 302, the twisting of the shadow mask 104 can further be prevented, as described above.

Also, the surface of the frame 102 as well as the second surface 302 of the shadow mask 104 maybe uneven. Specifically, for example, each of the first frame surface 102a and the second frame surface 102b of the frame 102 maybe formed uneven. The second frame surface 102b may be more uneven than the first frame surface 102a. According to this configuration, the vapor deposition material deposited on the second frame surface 102b of the frame 102 is prevented from coming off and contaminating the vapor deposition source 602 (FIG. 6) arranged on the side of the second frame surface and the inside of the sputtering device or the like.

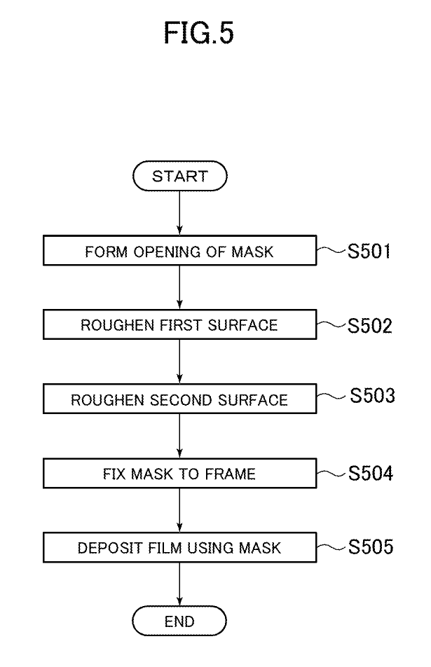

Next, the manufacturing process in the method of manufacturing the shadow mask 104 in the embodiment and a display device including a light emitting element layer formed using the shadow mask 104 in the embodiment will be described. FIG. 5 is a flowchart showing the method of manufacturing the display device in an embodiment of the invention. First, a thin plate of an invar material is stamped, thus forming the opening 200 of the shadow mask 104 (S501). However, this method is not limiting since the related-art technique may be used as a method for providing the opening 200 in the shadow mask 104.

Subsequently, the first surface 300 of the shadow mask 104 is roughened (S502). Specifically, for example, chemical processing such as etching or matt finish is performed on the first surface 300 of the shadow mask 104, thereby irregularly roughening the first surface 300. Moreover, the second surface 302 of the shadow mask 104 is roughened (S503). Here, the method for roughening the second surface 302 of the shadow mask 104 is chemical processing as in the case of roughening the first surface 300. However, the second surface 302 is roughened in such a way that the shape, size and the like of the tops and bottoms formed by the surface roughening differ from the shape, size and the like of the tops and bottoms formed on the first surface 300, as described above.

Either one of the surface roughening of the first surface 300 and the surface roughening of the second surface 302 may be carried out first. Then, the shadow mask 104 with its surfaces roughened is fixed to the frame 102 by welding (S504). The step 5504 completes the shadow mask 104 having the first surface 300 and the second surface 302.

Next, with the first surface 300 facing a substrate 600, and the second surface 302 arranged in such a way as to be exposed to a film deposition material, a light emitting element layer is formed while being patterned by vapor deposition (S505). Specifically, as shown in FIG. 6, first, in a film deposition device such as a vapor deposition device, the shadow mask 104 is fixed in such a way that the first surface 300 faces the substrate 600. Next, from a vapor deposition source 602 arranged on the side of the second surface 302, molecules of the film deposition material are discharged toward the substrate 600 with the shadow mask 104 fixed thereto. The discharged molecules are deposited on the surface of the second surface 302 of the shadow mask 104 and on the surface of the substrate 600 exposed through the opening 200 provided in the shadow mask 104.

Then, as the fixed shadow mask 104 is eliminated from the substrate 600, a film of a shape corresponding to the opening 200 formed in the shadow mask 104 is formed on the substrate 600. The resulting film includes a light emitting element film made of a light emitting material, and an electrode for supplying a current to the light emitting film, corresponding to each subpixel in the display panel, for example, as shown in FIG. 2. The step 5505 completes the display panel including the light emitting element layer. Although the method of manufacturing the display device includes the process of forming a film of a shape other than the shape corresponding to the opening 200, the process of completing the display device by incorporating the display panel into a casing, and the like, these processes will not be described here. The method of depositing molecules of the film deposition material is not limited to vapor deposition and may be other methods such as sputtering. According to the manufacturing method, the film deposition material is deposited not only on the surface of the display panel but also on the second surface 302 of the shadow mask 104. However, according to the embodiment, since the second surface 302 has an uneven surface, the film deposition material deposited on the second surface 302 will come off less easily than in with the case that surface is even. Therefore, the risk of contamination of the vapor deposition source 602 by the film deposition material that has come off, and the risk of entry of impurities into the display panel can be reduced. Moreover, the risk of entry of impurities into the display panel can be reduced further by the second frame surface of the frame 102 has an uneven surface.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A shadow mask comprising:
a first surface arranged in such a way as to face a film deposition target; and
a second surface arranged in such a way as to be exposed to a film deposition material,
wherein each of the first surface and the second surface has an uneven surface, and
the second surface is more uneven than the first surface.

2. The shadow mask according to claim 1, wherein
the first surface has a planar irregular shape, and
the second surface has a planar regular shape.

3. The shadow mask according to claim 1, wherein
an average value of one or more heights and one or more depths from a reference surface, of one or more tops and one or more bottoms in the uneven surface, is greater on the second surface than on the first surface.

4. The shadow mask according to claim 3, wherein
an average value of a space between one or more tops and one or more bottoms in the uneven surface as viewed in a plan view is greater on the second surface than on the first surface.

5. The shadow mask according to claim 1, wherein
the planar regular shape on the second surface is in such a shape that the bottoms are surrounded by tops continuously.

6. The shadow mask according to claim 1, wherein
the tops and the bottoms are formed in the shape of a lattice as viewed in a plan view.

7. The shadow mask according to claim 1, wherein
the tops and the bottoms are formed in the shape of stripes as viewed in a plan view.

8. The shadow mask according to claim 1, wherein
the tops and the bottoms are formed in the shape of circles as viewed in a plan view.

9. The shadow mask according to claim 1, wherein
a frame is provided in such a way as to hold a peripheral edge part of the shadow mask,
the frame has a first frame surface arranged on the side of the film deposition target, and a second frame surface arranged in such a way as to be exposed to the film deposition material,
each of the first frame surface and the second frame surface has an uneven surface, and
the second frame surface is more uneven than the first frame surface.

10. A method of manufacturing a display device including a light emitting element layer, the method comprising:
preparing a shadow mask having a first surface and a second surface, wherein each of the first surface and the second surface has an uneven surface and wherein the second surface is more uneven than the first surface; and
arranging the shadow mask in such away that the first surface faces a substrate while the second surface is exposed to a film deposition material, and forming the light emitting element layer while patterning the layer by vapor deposition.
